(19) United States
(12) Patent Application Publication
(10) Pub. No.: US 2026/0271465 A1
(43) Pub. Date: Sep. 10, 2026

(54) STRUCTURAL MEMBER, LIGHT-EMITTING SUBSTRATE, BACKLIGHT MODULE AND DISPLAY DEVICE

(71) Applicants: BOE MLED Technology Co., Ltd., Beijing (CN); BOE Technology Group Co., Ltd., Beijing (CN)

(72) Inventors: Xiaofei XU, Beijing (CN); Zhongbao WU, Beijing (CN); Jingran NIU, Beijing (CN); Enmin NIU, Beijing (CN); Shouwei WANG, Beijing (CN); Kun LU, Beijing (CN); Yubiao LI, Beijing (CN)

(73) Assignees: BOE MLED Technology Co., Ltd., Beijing (CN); BOE Technology Group Co., Ltd., Beijing (CN)

(21) Appl. No.: 18/852,809

(22) PCT Filed: Nov. 1, 2023
(86) PCT No.: PCT/CN2023/129100

§ 371 Date: Sep. 30, 2024

(51) Int. Cl. H10H 29/854; G02F 1/13357; H10H 29/49

(52) U.S. Cl. CPC H10H 29/854; G02F 1/133603; H10H 29/49

(57) ABSTRACT

A structural member is provided. The structural member includes two main body portions, a connection portion and two first bonding portions. The two main body portions extend in a first direction and have a first interval therebetween in a second direction. Each main body portion includes a plurality of first electronic components disposed at intervals in the first direction. The connection portion extends in the second direction, and two ends of the connection portion are connected to ends of the two main body portions located on a same side. The two first bonding portions are connected to ends of the two main body portions away from the connection portion, and the first bonding portions are configured to be connected to connectors.

### CROSS-REFERENCE TO RELATED APPLICATION

This application is a national phase entry under 35 USC 371 of International Patent Application No. PCT/CN2023/129100, filed on Nov. 1, 2023, which is incorporated herein by reference in its entirety.

### TECHNICAL FIELD

The present disclosure relates to the field of display technologies, and in particular, to a structural member, a light-emitting substrate, a backlight module and a display device.

### BACKGROUND

With the development of light-emitting diode technologies, backlight modules using sub-millimeter light-emitting diodes (mini LEDs) and micro light-emitting diodes (micro LEDs) have been widely used. The size of the mini LED is about in a range of 100 μm to 300 μm, inclusive, and the size of the micro LED is about less than 100 μm. Due to small size, high brightness, high contrast and other advantages of the mini LED and the micro LED, when applied to the backlight module, the backlight module may include a plurality of dimming zones, and fine-tune is performed on each dimming zone to achieve display of high-dynamic range (HDR) images, thereby attracting more and more attention.

### SUMMARY

In an aspect, a structural member is provided. The structural member includes two main body portions, a connection portion and two first bonding portions. The two main body portions extend in a first direction and have a first interval therebetween in a second direction. Each main body portion includes a plurality of first electronic components disposed at intervals in the first direction. The first direction and the second direction intersect each other. The connection portion extends in the second direction, and two ends of the connection portion are connected to ends of the two main body portions located on a same side. The two first bonding portions are connected to ends of the two main body portions away from the connection portion, and the two first bonding portions are configured to be connected to connectors.

In some embodiments, an interval between two adjacent first electronic components in the second direction is D_{y}, a dimension of the main body portion in the second direction is D₂, and D_{y} and D₂ satisfy: D_{y}=3D₂+3M, where M is in a range of 0 mm to 2 mm, inclusive.

In some embodiments, an interval between two adjacent first electronic components in the second direction is D_{y}, a dimension of the main body portion in the second direction is D₂, and D_{y} and D₂ satisfy: D_{y}=2D₂+2M, where M is in a range of 0 mm to 2 mm, inclusive.

In some embodiments, the structural member is an aluminum-based structural member.

In another aspect, a light-emitting substrate is provided. The light-emitting substrate includes a backplane and at least one structural member group disposed on the backplane. The structural member group includes a plurality of first structural members, a plurality of first connectors, a plurality of second structural members and a plurality of second connectors. The plurality of first structural members each include the structural member as described in any of above embodiments. The plurality of first structural members are disposed at intervals on the backplane in the second direction, and the first structural member has a first opening. Each first bonding portion of each first structural member is connected to a first connector. The plurality of second structural members each include the structural member as described in any of above embodiments. The plurality of second structural members are disposed at intervals on the backplane in the second direction, the second structural member has a second opening, and an orientation of the first opening is opposite to an orientation of the second opening. Each first bonding portion of the second structural member is connected to a second connector. Two first connectors connected to two adjacent first structural members and having a smallest distance in the second direction are respectively connected to two second connectors connected to a same second structural member; and two second connectors connected to two adjacent second structural members and having a smallest distance in the second direction are respectively connected to two first connectors connected to a same first structural member.

In some embodiments, a number of the first structural members is one more than a number of the second structural members. The structural member group further includes two third structural members and outlet connectors. The two third structural members are located at both sides of the plurality of second structural members in the second direction, and the two third structural members both extend in the first direction. An end of a third structural member proximate to a first structural member is provided with a second bonding portion thereon, and an end of the third structural member away from the first structural member is provided with a third bonding portion thereon. The second bonding portion is connected to a second connector, and is connected to a first connector connected to the plurality of first structural members and located at an outermost side in the second direction through the second connector. An outlet connector is connected to the third bonding portion.

In some embodiments, a number of the second structural members is one more than a number of the first structural members. The structural member group further includes two third structural members and outlet connectors. The two third structural members are located at both sides of the plurality of first structural members in the second direction, and the two third structural members both extend in the first direction. An end of a third structural member proximate to a second structural member is provided with a second bonding portion thereon, and an end of the third structural member away from the second structural member is provided with a third bonding portion thereon. The second bonding portion is connected to a first connector, and is connected to a second connector connected to the plurality of second structural members and located at an outermost side in the second direction through the first connector. An outlet connector is connected to the third bonding portion.

In some embodiments, the third structural member include a plurality of second electronic components disposed at intervals in the first direction, and an interval between two adjacent second electronic components is equal to an interval between two adjacent first electronic components in the first structural member and an interval between two adjacent first electronic components in the second structural member.

In some embodiments, the third structural members are aluminum-based structural members, and the outlet connector and the second electronic components are disposed on a surface of the third structural member away from the backplane.

In some embodiments, the third structural members are epoxy board structural members, the second electronic components are disposed on a surface of the third structural member away from the backplane, and the outlet connector is disposed on a surface of the third structural member proximate to the backplane. The backplane includes a plurality of avoidance holes, and each outlet connector is disposed in an avoidance hole.

In some embodiments, the light-emitting substrate further includes a driving circuit board and a circuit board. The driving circuit board is disposed on a surface of the backplane away from the third structural member. An end of the circuit board is connected to the driving circuit board, and another end of the circuit board is connected to the outlet connectors.

In some embodiments, the driving circuit board is a flexible printed circuit or a printed circuit board, and the circuit board is a flexible flat cable.

In some embodiments, the light-emitting substrate includes a plurality of structural member groups that are arranged in the second direction, and a plurality of third structural members belonging to different structural member groups are arranged at intervals in the second direction.

In some embodiments, first electronic components of the first structural member and first electronic components of the second structural member, and second electronic components of a third structural member included in the structural member group are all light-emitting components. An included angle between a maximum light exit angle of a light-emitting component and a normal direction of the light-emitting component is α. A thickness of the first connector is T1, a distance between the first connector and a light-emitting component closest to the first connector in the first direction is L1, and T1≤L1×tan (90°−α). A thickness of the second connector is T2, a distance between the second connector and a light-emitting component closest to the second connector in the first direction is L2, and T2≤L2×tan (90°−α).

In some embodiments, a first connector and a second connector that are connected each other are board-to-board connectors.

In yet another aspect, a backlight module is provided. The backlight module includes a driving circuit board and the light-emitting substrate as described in any of the above embodiments. First electronic components of the first structural member and the second structural member of the light-emitting substrate, and second electronic components of a third structural member included in the structural member group all include light-emitting components. The driving circuit board is connected to the light-emitting substrate and is configured to transmit a control signal to the light-emitting substrate.

In yet another aspect, a display device is provided. The display device includes the above backlight module and a display panel. The display panel is disposed on a light-exit side of the backlight module.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a display device, in accordance with some embodiments;

FIG. 2 is a structural diagram of a display panel, in accordance with some embodiments;

FIG. 3A is a structural diagram of a wiring substrate, in accordance with some embodiments;

FIG. 3B is a structural diagram of another wiring substrate, in accordance with some embodiments;

FIG. 4 is an enlarged partial view of a region A in FIG. 3A;

FIG. 5 is a structural diagram of yet another wiring substrate, in accordance with some embodiments;

FIG. 6 is a structural diagram of a structural member, in accordance with some embodiments;

FIG. 7 is a structural diagram of a light-emitting substrate, in accordance with some embodiments;

FIG. 8 is a structural diagram of a third structural member, in accordance with some embodiments;

FIG. 9 is a connection structural diagram of an outlet connector and a third structural member, in accordance with some embodiments;

FIG. 10 is another connection structural diagram of an outlet connector and a third structural member, in accordance with some embodiments;

FIG. 11 is a structural diagram of another light-emitting substrate, in accordance with some embodiments;

FIG. 12 is a structural diagram of a backside of a light-emitting substrate, in accordance with some embodiments; and

FIG. 13 is a sectional view taken along a section line A-A in FIG. 7 or FIG. 11.

### DETAILED DESCRIPTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled” and “connected” and derivatives thereof may be used. For example, the term “connection” should be understood in a broad sense. For example, the “connection” may be a fixed connection, a detachable connection, or of an integrated structure; it may be a direct connection or an indirect connection by an intermediate medium.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” as used herein indicates an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plane views as idealized exemplary drawings. In the accompanying drawings, thicknesses of layers and sizes of areas/regions are enlarged for clarity. Variations in shapes relative to the accompanying drawings due to, for example, manufacturing technologies and/or tolerances may be envisaged. Therefore, the exemplary embodiments should not be construed to be limited to the shapes of areas/regions shown herein, but to include deviations in the shapes due to, for example, manufacturing. For example, an etched area/region shown in a rectangular shape generally has a feature of being curved. Therefore, the areas/regions shown in the accompanying drawings are schematic in nature, and their shapes are not intended to show actual shapes of the areas/regions in a device, and are not intended to limit the scope of the exemplary embodiments.

Some embodiments of the present disclosure provide a display device, and the display device may be any device that displays images whether in motion (such as a video) or fixed (such as a still image), and regardless of text or image.

For example, the display device may be a mobile phone, a wireless device, a personal digital assistants (PDA), a wearable device, an augmented reality (AR) device, a virtual reality (VR) device, a hand-held or portable computer, a global positioning system (GPS) receiver/navigator, a camera, an MPEG-4 Part 14 (MP4) video player, a video camera, a game console, a watch, a clock, a calculator, a TV monitor, a flat-panel display, a computer monitor, a car display (e.g., an odometer display), a cockpit controller and/or display, a camera view display (e.g., a display of rear view camera in vehicle), an electronic photo, an electronic billboard or sign, a projector, a packaging and aesthetic structure (e.g., a display for displaying an image of a piece of jewelry), etc.

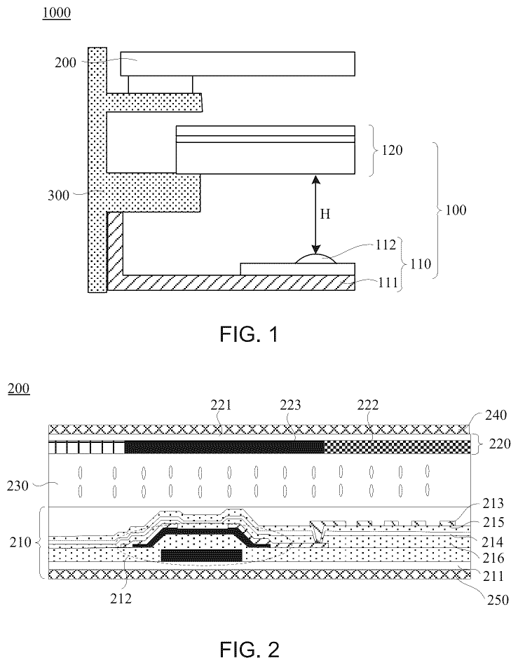

In some embodiments, the display device may be a liquid crystal display (LCD) device. Referring to FIG. 1, in a case where the display device 1000 is the liquid crystal display device, the display device 1000 may include a backlight module 100 and a display panel 200. Of course, the embodiments of the present disclosure do not limit thereto, and the display device 1000 may also include other structures or devices. For example, as shown in FIG. 1, the display device 1000 may further include a frame 300 and a glass cover plate (not shown in FIG. 1) provided on a display side of the display panel 200, as long as the same technical ideas as those of the present application are applied, and are not listed one by one here.

The display panel 200 has a display surface and a non-display surface. The display surface refers to a surface of the display panel 200 for displaying a picture (an upper surface of the display panel 200 in FIG. 1), and the non-display surface refers to a surface opposite to the display surface. The backlight module 100 is disposed on the non-display surface of the display panel 200 (a lower surface of the display panel 200 in FIG. 2), and the backlight module 100 is used for providing a light source for the display panel 200.

As shown in FIG. 2, in a case where the display device 1000 is the liquid crystal display device, the display panel 200 may be a liquid crystal display panel. In this case, the display panel 200 may include an array substrate 210, an opposite substrate 220, and a liquid crystal layer 230 provided between the array substrate 210 and the opposite substrate 220.

The array substrate 210 is provided thereon with thin film transistors (TFTs) 212 and pixel electrodes 213 that are located on a first substrate 211. The thin film transistor 212 includes an active layer, a source, a drain, a gate and a gate insulating layer. The source and the drain are in contact with the active layer, and the pixel electrode 213 is electrically connected to the drain of the thin film transistor 212.

As shown in FIG. 2, the array substrate 210 further includes a common electrode 214 provided on the first substrate 211. The pixel electrodes 213 and the common electrode 214 may be disposed in different layers. In this case, as shown in FIG. 2, a first insulating layer 215 is provided between the pixel electrodes 213 and the common electrode 214. In a case where the common electrode 214 is provided between a layer where the thin film transistors 212 are located and the pixel electrodes 213, as shown in FIG. 2, a second insulating layer 216 is further provided between the common electrode 214 and the thin film transistors 212.

The pixel electrodes 213 and the common electrode 214 may be disposed in the same layer (not shown in the figures). In this case, the pixel electrode 213 and the common electrode 214 are each of a comb structure including a plurality of stripe-shaped sub-electrodes. In some other embodiments, the common electrode 214 may be disposed in the opposite substrate 220.

As shown in FIG. 2, the opposite substrate 220 may include a color filter layer 222 disposed on a second substrate 221. In this case, the opposite substrate 220 may also be referred to as a color filter (CF) substrate. In a case where the backlight module 100 is used to emit white light, the color filter layer 222 at least includes a red photoresist unit, a green photoresist unit and a blue photoresist unit. The red photoresist unit, the green photoresist unit and the blue photoresist unit are opposite to sub-pixels in the display panel 200 by one to one. The opposite substrate 220 further includes a black matrix pattern 223 provided on the second substrate 221, and the black matrix pattern 223 are used to separate the red photoresist unit, the green photoresist unit and the blue photoresist unit.

As shown in FIG. 2, the display panel 200 may further include a first polarizer 240 disposed on a side of the opposite substrate 220 away from the liquid crystal layer 230, and a second polarizer 250 disposed on a side of the array substrate 210 away from the liquid crystal layer 230. In addition, the display panel 200 may further include other film layers or structures, which are not listed one by one in the embodiments of the present disclosure.

When the display device works, the backlight module 100 emits light towards the display panel 200. An electric field may be generated between the pixel electrode and the common electrode of the display panel, and liquid crystal molecules in the liquid crystal layer 230 are deflected due to action of the electric field, thereby achieving brightness adjustment (grayscale adjustment) of the light emitted by the backlight module 100. The light passing through the liquid crystal layer 230 is further directed towards the opposite substrate 220, and then exits after being colored by the color filter layer 222, thereby realizing image display.

As shown in FIG. 1, the backlight module 100 may include a light-emitting substrate 110 and optical films 120 provided on a side of the light-emitting substrate 110 proximate to the display panel 200. The light-emitting substrate 110 may directly emit white light. Alternatively, the light-emitting substrate 110 may emit light of other colors, and the light of other colors is directed towards the display panel 200 after color conversion by the optical films 120. For example, the light-emitting substrate 110 may emit blue light, and the optical films 120 may include a quantum dot film, the quantum dot film converts the blue light emitted by the light-emitting substrate into white light, and then the white light is directed towards the display panel. The optical films 120 may include a diffusion plate and/or an optical brightness enhancement film, which is not specifically limited in the embodiments of the present disclosure. The diffusion plate has a scattering and diffusion effect, and is capable of further mixing the above white light uniformly. The optical brightness enhancement film is capable of improving a light extraction efficiency of the backlight module 100. In addition, the backlight module 100 may further include other film layers or structures, which are not listed one by one in the embodiments of the present disclosure.

As shown in FIG. 1, the light-emitting substrate 110 includes a backplane 111 and a light source provided on the backplane 111. The light source includes a plurality of light-emitting components 112 (e.g., mini-LED chips or micro-LED chips) arranged in an array. There is a light mixing interval H between the light-emitting substrate 110 and the optical films 120. The light-emitting component 112 may be equivalent to a point light source. Lights emitted by adjacent light-emitting components 112 are initially mixed within the light mixing interval H and then directed to the optical films 120. After further homogenization by the optical films 120, the light is directed to the display panel 200. It can be understood that the light finally incident on the display panel may be equivalent to the light emitted by a surface light source.

In some embodiments, in some display products with a relatively large light mixing interval H (e.g., greater than 20 mm), an interval between adjacent light-emitting components 112 in the light-emitting substrate 110 is relatively large, and a light bar may be used to form the light-emitting substrate. The light-emitting substrate may be divided into a plurality of dimming zones, and fine-tune is performed on brightness of light-emitting components in each dimming zone. In a case where each dimming zone includes the same number of light-emitting elements, the larger an interval between the light-emitting components on the light bar, the larger an area of the dimming zone.

In the related art, the light bar may include U-shaped circuit boards, and the U-shaped circuit board is provided thereon with a plurality of light-emitting components and a first connector. In a case where a plurality of U-shaped circuit boards are arranged to assemble to form a light-emitting substrate, a transfer circuit board is further required. The transfer circuit board is provided thereon with a plurality of second connectors are provided on the transfer circuit board. The plurality of second connectors are arranged in two columns in a direction perpendicular to an extension direction of the transfer circuit board, and each column includes multiple second connectors arranged in the extension direction of the transfer circuit board. In the direction perpendicular to the extending direction of the transfer circuit board, U-shaped circuit boards are provided on both sides of the transfer circuit board, and first connectors on the U-shaped circuit boards on both sides are connected to the second connectors on the transfer circuit board. The transfer circuit board may be connected to an external circuit (e.g., a driving circuit board) by a flexible printed circuit (FPC). In the direction perpendicular to the extension direction of the transfer circuit board, two pairs of first connectors and second connectors that are interconnected are included between two adjacent U-shaped circuit boards, resulting in a large spacing between the light-emitting components on both sides of the transfer circuit board, which is not conducive to reducing the area of the dimming zones of the light-emitting substrate.

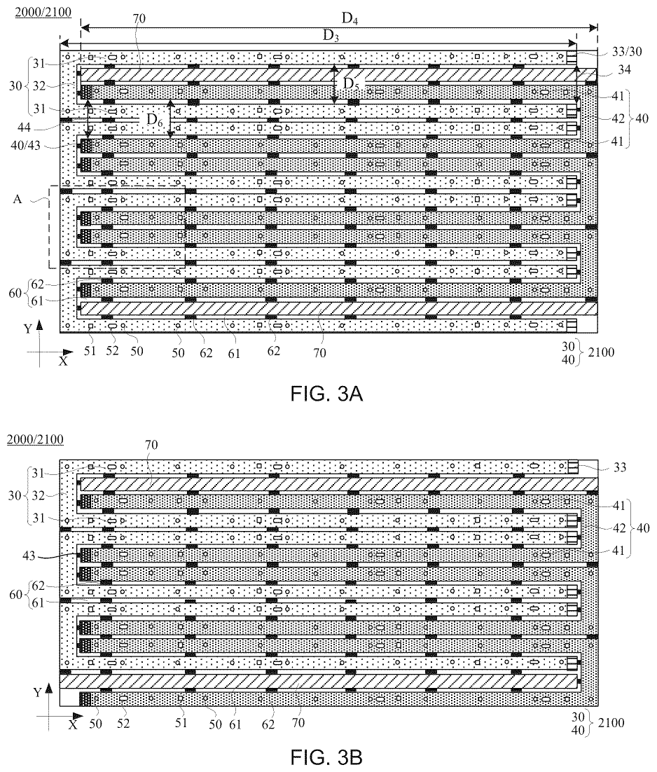

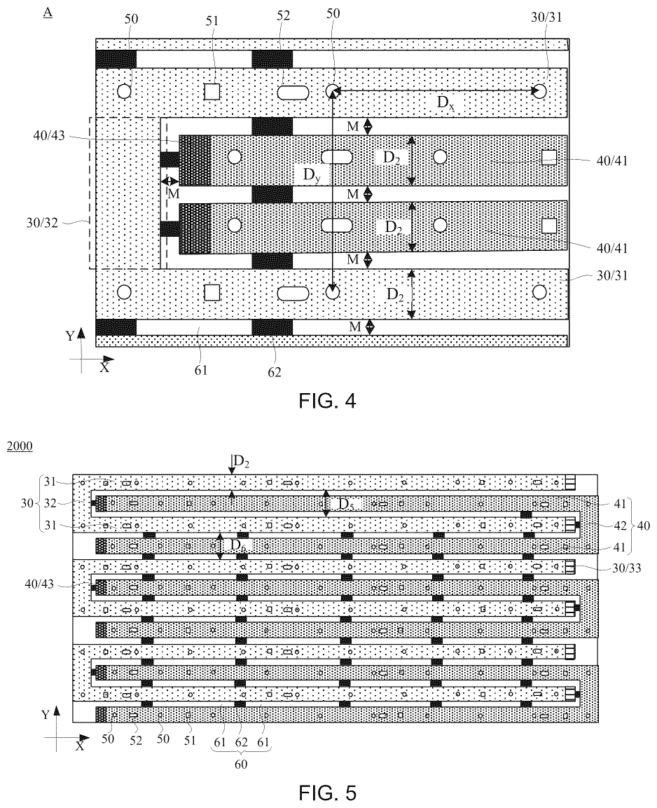

In order to solve the above technical problems, embodiments of the present disclosure provide a wiring structure 2000, which may be used to form a structural member. Referring to FIGS. 3A and 4, the wiring substrate 2000 includes a substrate 2100, and the substrate 2100 includes first areas 30 and second areas 40. In FIG. 3A, in order to clearly show boundaries and positions of the first area 30 and the second area 40, different types of filling patterns are used for both areas.

The material of the substrate 2100 may be any of glass, quartz, sapphire and ceramic; alternatively, the material of the substrate 2100 may be a semiconductor material, such as any of a single crystal semiconductor substrate based on silicon or silicon carbide as a base material, a polycrystalline semiconductor, a silicon or germanium compound semiconductor, or a silicon on insulator (SOI); alternatively, the material of the substrate 2100 may be an organic resin material including epoxy resin, triazine, silicone resin or polyimide. Alternatively, the substrate 2100 may be an epoxy board (FR4) type printed circuit board (PCB), or a flexible PCB that is prone to deformation; alternatively, the substrate 2100 may be made of any of a ceramic material including silicon nitride, AlN or Al₂O₃, or a metal or a metal compound, or a metal core printed circuit board (MCPCB) or a metal copper clad laminate (MCCL).

The first area 30 includes two first backbone regions 31, a first connection region 32 and two first bonding regions 33. The two first backbone regions 31 extend in the first direction X and have a second interval D5 therebetween in the second direction Y. The second interval D5 refers to a distance between the two first backbone regions 31 in the second direction Y. Ends of the first connection region 32 are respectively connected to ends (e.g., ends at the left in FIG. 3A) of the two first backbone regions 31 located on the same side. The two first bonding regions 33 are respectively connected to ends of the two first backbone regions 31 away from the first connection region 32, and each first bonding region 33 is configured to be connected to a first connector. The first area 30 forms a U-shaped structure, and the first area 30 has a third opening 34. The third opening 34 refers to a region between the two first backbone regions 31. An orientation of the third opening 34 is a direction away from the first connection region 32, that is, a direction from left to right in FIG. 3A. The first direction X and the second direction Y intersect with each other. For example, the first direction X and the second direction Y are perpendicular to each other.

The second area 40 includes two second backbone regions 41, a second connection region 42 and two second bonding regions 43. The two second backbone regions 41 extend in the first direction X and have a third interval De therebetween in the second direction Y. The third interval De refers to a distance between the two second backbone regions 41 in the second direction Y. Ends of the second connection region 42 are respectively connected to ends (e.g., ends at the right in FIG. 3A) of the two second backbone regions 41 located on the same side. The two second bonding regions 43 are respectively connected to ends of the two second backbone regions 41 away from the second connection region 42, and each second bonding region 43 is configured to be connected to a second connector. The second area 40 forms a U-shaped structure, and the second area 40 has a fourth opening 44. The fourth opening 44 refers to a region between the two second backbone regions 41. An orientation of the fourth opening 44 is a direction away from the second connection region 42, that is, a direction from right to left in FIG. 3A.

As shown in FIG. 3A, the orientation (from right to left in the first direction X in FIG. 3A) of the fourth opening 44 is opposite to the orientation (from left to right in the first direction X in FIG. 3A) of the third opening 34, so that the first backbone region 31 can extend into the fourth opening 44, and the second backbone region 41 can extend into the third opening 34. For example, two first backbone regions 31 that belong to two adjacent first areas 30 and have the smallest distance in the second direction Y are located in the fourth opening 44 of the same second area 40; and two second backbone regions 41 that belong to two adjacent second areas 40 and have the smallest distance in the second direction Y are located in the third opening 34 of the same first area 30. Based on this, it is beneficial to increase the space utilization of the substrate 2100. A wiring substrate 2000 may be cut to form a plurality of structural members, and any first area 30 and any second area 40 are each used to form an independent structural member (e.g., a structural member that may be used as a light source). Each first area 30 and each second area 40 are both of U-shaped structures.

In some embodiments, referring to FIG. 3A, a dimension D₃ of the first backbone region 31 in the first direction X is equal to a dimension D₄ of the second backbone region 41 in the first direction X. And/or, referring to FIG. 4, a dimension of the first backbone region 31 in the second direction Y is equal to a dimension of the second backbone region 41 in the second direction Y, and the dimensions of the first backbone region 31 and the second backbone region 41 in the second direction Y are both D₂. In this way, a first backbone region 31 and a second backbone region 41 of the same size and the same shape may be formed. The first backbone region 31 and the second backbone region 41 are used to provide first electronic components 50. The first electronic component 50 is, for example, a light-emitting component, a sensor or other components arranged in an array. The first backbone region 31 and the second backbone region 41 are the same in size and shape, which is conducive to improving the uniformity of arrangement of the first electronic components 50 on the first backbone region 31 and the second backbone region 41.

It can be understood that in a case where the first electronic component 50 is a light-emitting component, the structural member formed by cutting the wiring substrate 2000 is a light-emitting structural member. From the perspective of the type of the light-emitting component, the light-emitting component may be a LED with a quantum well junction, a LED with a columnar structure, a LED with a double heterojunction, or the like. The light-emitting component may further include an encapsulation structure on a light-exit side of the LED. The encapsulation structure may be made of a transparent material, and a surface of the encapsulation structure may be a curved surface or a hemispherical surface. From the perspective of the size of the light-emitting component, the light-emitting component may be a structure with a size miniaturized to an order of hundreds of microns. For example, a light-emitting area of the LED in the light-emitting component may be less than 1 mm², or the light-emitting area of the LED may be less than 10000 μm², or the light-emitting area of the LED may be less than 3000 μm², or the light-emitting area of the LED may be less than 700 μm². Of course, the embodiments of the present disclosure do not limit thereto. The light-emitting components may also adopt light-emitting components of other structures, as long as the same technical ideas as those of the present application are applied.

In some embodiments, as shown in FIG. 3A, the second interval D₅ is equal to the third interval D₆. In this way, the first area 30 and the second area 40 having the same size and the same shape may be formed, so that the first area 30 and the second area 40 may form structural members with the same shape, thereby improving consistency and versatility of the structural members.

For example, a dimension of the first connection region 32 of the first area 30 in the first direction X is equal to a dimension of the second connection region 42 of the second area 40 in the first direction X. Further, since the second interval D₅ is equal to the third interval D₆, a dimension of the first connection region 32 of the first area 30 in the second direction Y is equal to a dimension of the second connection region 42 of the second area 40 in the second direction Y. In this way, the first backbone region 31 of the first area 30 may be completely located within the fourth opening 44 of the second area 40, and the second backbone region 41 of the second area 40 may be completely located within the third opening 34 of the first area 30. Thus, the space utilization of the third opening 34 and the fourth opening 44 may be improved, thereby improving the space utilization of the wiring substrate 2000 and reducing the manufacturing cost of the wiring substrate 2000.

In some embodiments, as shown in FIGS. 3A and 4, the second interval D₅ is greater than 2 times the dimension D₂ of the second backbone region 41 in the second direction Y, and less than or equal to 2.5 times the dimension D₂ of the second backbone region 41 in the second direction Y. That is, 2D₂<D₅≤2.5D₂. In this case, the two second backbone regions 41 of the second area 40 are respectively located in the third openings 34 of two adjacent first areas 30, and only two second backbone regions 41 are disposed in each third opening 34.

The third interval D₆ is greater than 2 times the dimension D₂ of the first backbone region 31 in the second direction Y, and less than or equal to 2.5 times the dimension D₂ of the first backbone region 31 in the second direction. That is, 2D₂<D₆≤2.5D₂. In this case, the two first backbone regions 31 of the first area 30 are respectively located in the fourth openings 44 of two adjacent second areas 40, and two first backbone regions 31 of two adjacent first areas 30 are disposed in a fourth opening 44, that is, two first backbone regions 31 may be disposed in each fourth opening 44.

The setting of “2D₂<D₅≤2.5D₂” and “2D₂<D₆≤2.5D₂” may not only provide two second backbone regions 41 belonging to two second areas 40 and adjacent to each other in the same third opening 34, but also provide two first backbone regions 31 belonging to two first areas 30 and adjacent to each other in the same fourth opening 44, and is further beneficial to setting a gap between the first backbone region 31 and the second backbone region 41, so as to subsequently separate the first area 30 and the second area 40 at the gap between the first backbone region 31 and the second backbone region 41.

As shown in FIG. 3A, the substrate 2100 includes a plurality of first areas 30 sequentially arranged in the second direction Y, and a plurality of second areas 40 sequentially arranged in the second direction Y. Two first backbone regions 31 that belong to two adjacent first areas 30 and have the smallest distance in the second direction Y are located in the fourth opening 44 of the same second area 40. Two second backbone regions 41 that belong to two adjacent second areas 40 and have the smallest distance in the second direction Y are located in the third opening 34 of the same first area 30. In this way, the third opening 34 may be used to provide the second backbone region 41, and the fourth opening 44 may be used to provide the first backbone region, which is beneficial to improving the space utilization of the wiring substrate 2000.

As shown in FIG. 3A, in a case where the two first backbone regions 31 that belong to two adjacent first areas 30 and have the smallest distance in the second direction Y are located in the fourth opening 44 of the same second area 40, and the two second backbone regions 41 that belong to two adjacent second areas 40 and have the smallest distance in the second direction Y are located in the third opening 34 of the same first area 30, in order to make a rather good use of the space of the substrate 2100, a third area 70 may be provided between a first area 30 and a second area 40 that are closest to an edge in the second direction Y, and the third area is located between the first backbone region 31 and the second backbone region 41 that are closest to the edge in the second direction Y. The third area 70 and the first area 30, as well as the third area 70 and the second area 40, are connected by connection structures 62. Two adjacent connection structures 62 are provided with a through hole 61 to reduce a connection region between the third area 70 and the first area 30 and a connection region between the third area 70 and the second area 40, so as to facilitate the subsequent separation of the third area 70 from the first area 30 and the second area 40.

For example, two outermost sides of the substrate 2100 in the second direction Y may each be a first area 30 or a second area 40. For example, as shown in FIG. 3A, an upper side and a lower side of the substrate 2100 in the second direction Y are both the first areas 30; alternatively, as shown in FIG. 3B, an upper side of the substrate 2100 in the second direction Y is a first area 30, and a lower side of the substrate 2100 in the second direction Y is a second area 40. Of course, two sides of the substrate 2100 in the second direction Y may both be the second areas 40 (not shown in the figures); alternatively, an upper side of the substrate 2100 in the second direction Y is a second area 40, and a lower side of the substrate 2100 in the second direction Y is a first area 30 (not shown in the figures).

With continued reference to FIGS. 3A and 4, a plurality of through holes 61 are included between a first area 30 and a second area 40 that are adjacent, between a first area 30 and a third area 70 that are adjacent, between a first area 30 and a first area 30 that are adjacent, between a second area 40 and a second area 40 that are adjacent, and between a second area 40 and a third area 70 that are adjacent. A connection structure 62 is included between two adjacent through holes 61. The connection structures 62 are used to connect and fix the first area 30 and the second area 40 that are adjacent, the first area 30 and the third area 70 that are adjacent, the first area 30 and the first area 30 that are adjacent, the second area 40 and the second area 40 that are adjacent, and the second area 40 and the third area 70 that are adjacent. The connection structures 62 connect the first areas 30, the second areas 40 and the third areas 70 to form a whole, which is beneficial to providing a wiring layer on the first areas 30 and the second areas 40 of the substrate 2100 during manufacturing the wiring substrate. Through holes 61 extend through the substrate 2100 between connection structures 62, which is beneficial to reducing contact areas between the first areas 30, the second areas 40 and the third areas 70, so as to facilitate the separation of the first area 30 and the second area 40 in the subsequent manufacturing process to form independent structural members.

In some embodiments, as shown in FIGS. 3A and 4, a plurality of first electronic components 50 are disposed at intervals in the first direction X in each first backbone region 31 of the first area 30, and a plurality of first electronic components 50 are disposed at intervals in the first direction X in each second backbone region 41 of the second area 40. For example, the first electronic components 50 are disposed in the middle of the first backbone region 31 in the second direction Y and in the middle of the second backbone region 41 in the second direction Y. A width of the connection structure 62 in a direction perpendicular to a boundary of the first area 30 or the second area 40 connected to the connection structure 62 is M.

For example, in an extension direction of an edge of the first area 30 or the second area 40, a length of the through hole 61 is greater than a length of the connection structure 62. In a direction perpendicular to the boundary of the first area 30 or the second area 40 where the connection structure 62 is located, a width of the connection structure 62 is M, and M may be in a range of 1 mm to 2 mm, inclusive. For example, in an interval between the first backbone region 31 and the second backbone region 41 in the second direction Y, the width M of the connection structure 62 in the second direction Y is in a range of 0 mm to 2 mm, inclusive; and in an interval between the first backbone region 31 and the second backbone region 41 in the first direction X, the width M of the connection structure 62 in the first direction X is in a range of 0 mm to 2 mm, inclusive. For example, the width M of the connection structure 62 is 1 mm, 1.5 mm or 2 mm.

A line connecting geometric centers of multiple first electronic components 50 in any first backbone region 31 or second backbone region 41 is coincided with a center line of the first backbone region 31 or the second backbone region 41 where the first electronic components 50 are located in the first direction X. In addition, an interval D_{y} between two adjacent first electronic components 50 in the second direction Y, D₂ and M satisfy that D₂=(D_{y}−3M)/3, or D_{y}=3D₂+3M. As shown in FIG. 4, in this way, a distance between two adjacent first electronic components 50 on two first backbone regions 31 belonging to the same first area 30 in the second direction Y is equal to a sum of a dimension (2×(½×D₂)) of a first backbone region 31 in the second direction Y, dimensions (2×D₂) of two second backbone regions 41 in the second direction Y, and dimensions (3M) of three connection structures 62 in the second direction Y.

An interval between two adjacent first electronic components 50 on two first backbone regions 31 belonging to the same first area 30 in the first direction X is Dₓ; alternatively, an interval between two adjacent first electronic components 50 on two second backbone regions 41 belonging to the same second area 40 in the first direction X is also Dₓ. Furthermore, the distribution density of the first electronic components 50 in the first direction X may be the same as the distribution density of the first electronic components 50 in the second direction Y, that is, Dₓ=D_{y}. Of course, the distribution density of the first electronic components 50 in the first direction X may be different from the distribution density of the first electronic components 50 in the second direction Y, which is not limited in the present disclosure.

As shown in FIGS. 3A and 4, each first backbone region 31 of the first area 30 and each second backbone region 41 of the second area 40 are both provided with a plurality of driving elements 51, and the driving element 51 is configured to control at least one first electronic component 50 in the same area (e.g., the same first backbone region 31 or the same second backbone region 41). For example, in a case where the first electronic component 50 is a light-emitting component (e.g., a mini-LED chip), the driving element 51 may be a micro integrated circuit chip. A driving element 51 may control multiple light-emitting components. The multiple light-emitting components may be connected in series, in parallel, or in a combination of series and parallel; alternatively, the multiple light-emitting components may be independent, which is not specifically limited here.

In some embodiments, as shown in FIG. 4, each first backbone region 31 of the first area 30 and each second backbone region 41 of the second area 40 are both provided with a plurality of fixing holes 52, and the fixing hole 52 is used to fix and connect the structural member formed from the wiring substrate 2000 to other components, for example, fix the structural member to the backplane. The wiring substrate further includes encapsulation adhesives (not shown in the figures), and each encapsulation adhesive covers a first electronic component 50 and is used to protect the first electronic component 50.

In some other embodiments, referring to FIG. 5, the second interval D₅ is greater than the dimension D₂ of the second backbone region 41 in the second direction Y, and less than or equal to 1.5 times the dimension D₂ of the second backbone region 41 in the second direction Y, that is, D₂<D₅≤1.5D₂. In this case, a second backbone region 41 of the second area 40 is located in a third opening 34 of a first area 30, and another second backbone region 41 of the second area 40 is located between two adjacent first areas 30, that is, only one second backbone region 41 is provided in each third opening 34.

The third interval D₆ is greater than the dimension D₂ of the first backbone region 31 in the second direction Y, and less than or equal to 1.5 times the dimension D₂ of the first backbone region 31 in the second direction, that is, D₂<D₆≤1.5D₂. In this case, a first backbone region 31 of the first area 30 is located in a fourth opening 44 of a second area 40, and another first backbone region 31 of the first area 30 is located between two adjacent second areas 40, that is, only one first backbone region 31 is provided in each fourth opening 44.

The setting of “D₂<D₅≤1.5D₂ and D₂<D₆≤1.5D₂” may not only provide a second backbone region 41 in the third opening 34 and provide a first backbone region 31 in the fourth opening 44, but also be beneficial to setting a gap between the first backbone region 31 and the second backbone region 41, which is beneficial to subsequently separating the first area 30 and the second area 40 at the gap between the first backbone region 31 and the second backbone region 41.

In some other embodiments, referring to FIG. 5, a line connecting geometric centers of multiple first electronic components 50 in any first backbone region 31 or second backbone region 41 is coincided with a center line of the first backbone region 31 or the second backbone region 41 where the first electronic components 50 are located in the first direction X. In addition, D_{y}, D₂ and M satisfy that D₂=(D_{y}−2M) /2, or D_{y}=2D₂+2M. As shown in FIG. 5, in this way, a distance between two adjacent first electronic components 50 on two first backbone regions 31 belonging to the same first area 30 in the second direction Y is D_{y}, and is equal to a sum of a dimension (½×D₂) of a first backbone region 31 in the second direction Y, a dimension D₂ of a second backbone region 41 in the second direction Y, and dimensions (2M) of two connection structures 62 in the second direction Y.

The dimension of the first backbone region 31 in the second direction Y and the dimension of the second backbone region 41 in the second direction Y are both D₂. In this way, an interval between two adjacent first electronic components 50 on two first backbone regions 31 belonging to the same first area 30 in the second direction Y is D_{y}, or an interval between two adjacent first electronic components 50 on two second backbone regions 41 belonging to the same second area 40 in the second direction Y is also D_{y}. Thus, the distribution density of the first electronic components 50 in the first direction X is the same as the distribution density of the first electronic components 50 in the second direction Y.

For example, referring to FIG. 5, a plurality of through holes 61 are included between a first area 30 and a second area 40 that are adjacent. A connection structure 62 is included between two adjacent through holes 61, and the connection structure 62 is used to connect and fix the first area 30 and the second area 40 that are adjacent. The connection structure 62 connects the first area 30 and the second area 40 as a whole, which is beneficial for wiring on the first areas 30 and the second areas 40 of the substrate 2100 during manufacturing the wiring substrate. Through holes 61 extend through the substrate 2100 between connection structures 62, which is beneficial to reducing a contact area between the first area 30 and the second area 40, so as to facilitate the separation of the first area 30 and the second area 40 in the subsequent manufacturing process to form independent structural members. A plurality of through holes 61 and a plurality of connection structures 62 constitute a fourth area 60 together, and the fourth area 60 separates two adjacent first areas 30 and/or second areas 40, so that any first area 30 and any second area 40 may be separated at the fourth area 60 to form independent structural members subsequently.

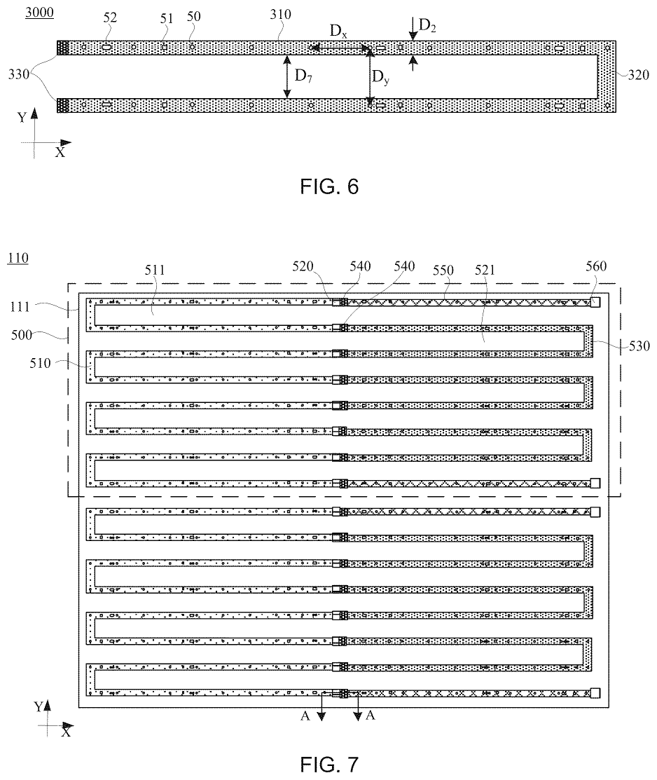

Some embodiments of the present disclosure further provide a structural member 3000. Referring to FIG. 6, the structural member 3000 may be formed by cutting the wiring substrate described in any of the above embodiments, and any first area 30 and any second area 40 on the wiring substrate are independent from each other and each form a structural member.

The structural member 3000 may include two main body portions 310, a connection portion 320 and two first bonding portions 330. The two main body portions 310 extend in the first direction X and have a first interval D₇ in the second direction Y. Each main body portion 310 includes a plurality of first electronic components 50 at intervals arranged in the first direction X. The connection portion 320 extends in the second direction Y, and two ends of the connection portion 320 are connected to ends of the two main body portions 310 located on a same side (e.g., the right side in FIG. 6). The two first bonding portions 330 are connected to ends (left ends in FIG. 6) of the two main body portions 310 away from the connection portion 320, and the first bonding portions 330 are each configured to be connected to a connector. That is, the structural member 3000 is a U-shaped structural member. Compared with a linear structural member, when the U-shaped structural member is assembled to form a light-emitting substrate, the use of connectors may be reduced, thereby reducing the manufacturing cost of the light-emitting substrate.

As shown in FIG. 6, the main body portion 310 further includes a plurality of driving elements 51 and fixing holes 52. The driving element 51 is used to drive at least one first electronic component 50 in the same area (e.g., the same main body portion 310). The fixing hole 52 is used to fix and connect the structural member 3000 to other components, for example, fix and connect the structural member 3000 to the backplane.

The first bonding portion 330 of the U-shaped structural member is provided at an end of the main body portion 310 away from the connection portion 320. When the plurality of structural members are assembled to form the light-emitting substrate, the plurality of structural members may be arranged in an S shape and connected in sequence by connectors (as shown in FIG. 7). This is beneficial to reducing an interval between structural members that are connected each other and reducing the minimum interval between adjacent first electronic components. In a case where each dimming zone includes the same number of first electronic components, areas of the dimming zones of the light-emitting substrate may be reduced, thereby improving the dimming accuracy of the light-emitting substrate.

For example, in a case where the first area of the wiring substrate forms the above structural member, each first backbone region of the first area forms a main body portion, the first connection region of the first area forms a connection portion, and each first bonding region of the first area forms a bonding portion. In a case where the second area of the wiring substrate forms the above structural member, each second backbone region of the second area forms a main body portion, the second connection region of the second area forms a connection portion, and each second bonding region of the second area forms a bonding portion. Since the first area and the second area are the same in size and shape, structural members formed by the first area and the second area have the same structures.

In some embodiments, an interval between two adjacent first electronic components 50 in the second direction Y is D_{y}, a dimension of the main body portion 310 in the second direction Y is D₂, and D_{y} and D₂ satisfy: D_{y}=3D₂+3M, where M is in a range of 0 mm to 2 mm, inclusive. The structural members may be formed by the wiring substrate as described in the above embodiments, and the arrangement densities of the first area and the second area on the wiring substrate may be improved, thereby improving the space utilization of the wiring substrate and reducing the manufacturing cost of the structural member 3000.

In some embodiments, an interval between two adjacent first electronic components 50 in the second direction Y is D_{y}, a dimension of the main body portion 310 in the second direction Y is D₂, and D_{y} and D₂ satisfy: D_{y}=2D₂+2M, where M is in a range of 0 mm to 2 mm, inclusive.

The structural member 3000 may be an aluminum-based structural member. The aluminum-based structural member includes a wiring layer (copper layer), and the wiring layer is used to design a circuit structure. The circuit structure is electrically connected to the first electronic components 50 and other electronic components (e.g., the driving elements 52) on the structural member 3000, thereby transmitting electrical signals to the first electronic components 50 and other electronic components. The use of the aluminum-based structural member is beneficial to reducing the manufacturing cost of the structural member 3000.

Referring to FIG. 7, some embodiments of the present disclosure further provide a light-emitting substrate 110. The light-emitting substrate 110 includes a backplane 111 and at least one structural member group 500 disposed on the backplane 111. The structural member group 500 includes a plurality of first structural members 510, a plurality of first connectors 520, a plurality of second structural members 530 and second connectors 540.

It can be understood that the plurality of first structural members 510 and the plurality of second structural members 530 may all be the structural members as described in the above embodiments, that is, the first structural members 510 and the second structural members 530 have the same structures. In FIG. 7, the first structural member 510 and the second structural member 530 use different filling patterns that are only used to distinguish arrangement positions of the two. In a case where the structural member 3000 is used to assemble to form the light-emitting substrate 110, the first electronic components 50 included in the first structural member 510 and the first electronic components 50 included in the second structural member 530 are all light-emitting components. As for the structure and the type of the light-emitting component, reference may be made to the above contents, and details are not repeated here.

The plurality of first structural members 510 are disposed at intervals on the backplane 111 in the second direction Y. Each first structural member 510 has a first opening 511. An orientation of the first opening 511 is a direction from left to right in FIG. 7. Each first structural member 510 has a first bonding portion (not shown in the figure) connected to a first connector 520.

The plurality of second structural members 530 are disposed at intervals on the backplane 111 in the second direction Y. The plurality of first structural members 510 and the plurality of second structural members 530 are disposed side by side in the first direction X. Each second structural member 530 has a second opening 521. An orientation of the second opening 521 is a direction from right to left in FIG. 7. Each second structural member 530 has a first bonding portion 330 connected to a second connector 540.

The orientation of the first opening 511 is opposite to the orientation of the second opening 521, so that the first bonding portion 330 of the first structural member 510 and the first bonding portion 330 of the second structural member 530 are provided opposite to each other, and the first connector 520 connected to the first structural member 510 and the second connector 540 connected to the second structural member 530 are plugged into each other. The first structural member 510 and the second structural member 530 are connected by the first connector 520 and the second connector 540, which is beneficial to reducing the difficulty in assembling the first structural member 510 and the second structural member 530, thereby improving the assembly efficiency. Moreover, only a pair of first connector 520 and second connector 540 connected to each other is needed to connect the first structural member 510 and the second structural member 530. Compared with the prior art, a pair of first connector 520 and second connector 540 connected to each other may be reduced between the first structural member 510 and the second structural member 530, which is beneficial to reducing an interval between two first electronic components 50 that belong to the first structural member 510 and the second structural member 530 and are closest to each other in the first direction X. In addition, calculated based on sizes of connectors with the same size in the related art, the interval between the two first electronic components 50 may be reduced from 52 mm to 34.4 mm, so as to adapt to a light-emitting substrate with a rather small interval between light-emitting components. In some other embodiments, sizes of the first connector 520 and the second connector 540 may also be reduced, so that the interval between the two first electronic components 50 that belong to the first structural member 510 and the second structural member 530 and are closest to each other in the first direction X may be reduced. In this way, the interval between two adjacent first electronic components 50 may further be reduced with other conditions unchanged, so as to achieve a light-emitting substrate with a rather small spacing between components. Furthermore, the first structural member 510 and the second structural member 530 may still be formed using the aluminum-based structural members, thereby reducing the manufacturing cost of the light-emitting substrate.

It can be understood that in order to make the light-emitting components on the light-emitting substrate have the same distribution density, different areas have equal or approximately equal luminous intensity. An interval between two first electronic components 50 that belong to a first structural member 510 and a second structural member 530 and are closest to each other in the first direction X is equal to an interval Dₓ between two adjacent first electronic components 50 on the first structural member 510 or the second structural member 530 in the first direction X; and an interval D_{y} between two adjacent first electronic components 50 on the first structural member 510 or the second structural member 530 in the second direction Y, an interval between two first electronic components 50 that belong to two adjacent first structural members 510 in the second direction Y and are closest to each other in the second direction Y, an interval between two first electronic components 50 that belong to two adjacent second structural members 530 in the second direction Y and are closest to each other in the second direction Y, and an interval between a first electronic component 50 and a second electronic component 553 that respectively belong to a second structural member 530 and a third structural member 550 (referring to the following text) adjacent to each other in the second direction Y and are closest to each other in the second direction Y are equal.

In some embodiments, the first connector 520 and the second connector 540 may be board-to-board (BTB) connectors. A first connector 520 and a second connector 540 having a connection relationship have the same number of connection terminals, and the two are adapted to be connected and fixed by plugging. For example, one of the first connector 520 and the second connector 540 is a male connector, and the other thereof is a female connector.

As shown in FIG. 7, two first connectors 520 connected to two adjacent first structural members 510 and having the smallest distance in the second direction Y are respectively connected to two second connectors 540 connected to the same second structural member 530. For example, in FIG. 7, in a direction from top to bottom, among four first connectors 520 connected to the first first structural member 510 and the second first structural member 510, the middle two first connectors 520 are respectively connected to two second connectors 540 connected to the first second structural member 530.

Two second connectors 540 connected to two adjacent second structural members 530 and having the smallest distance in the second direction Y are respectively connected to two first connectors 520 connected to the same first structural member 510. For example, in FIG. 7, in a direction from top to bottom, among four second connectors 540 connected to the first second structural member 530 and the second second structural member 530, the middle two second connectors 540 are respectively connected to two first connectors 520 connected to the second first structural member 510. In this way, the first structural member 510 and the second structural member 530 having a connection relationship may be connected only by a first connector 520 and a second connector 540 without proving a transfer circuit board, which is beneficial to reducing a distance between the first structural member 510 and the second structural member 530 in the first direction X, and further reducing the interval between the two first electronic components that belong to the first structural member 510 and the second structural member 530 respectively and are closest to each other in the first direction, thereby reducing the interval between the first electronic components. In a case where each dimming zone includes the same number of first electronic components, an area of the dimming zone may be reduced, thereby improving the dimming accuracy of the light-emitting substrate 110.

In some embodiments, as shown in FIG. 7, the number of the first structural members 510 is one more than the number of the second structural members 530. The structural member group 500 further includes two third structural members 550 and outlet connectors 560.

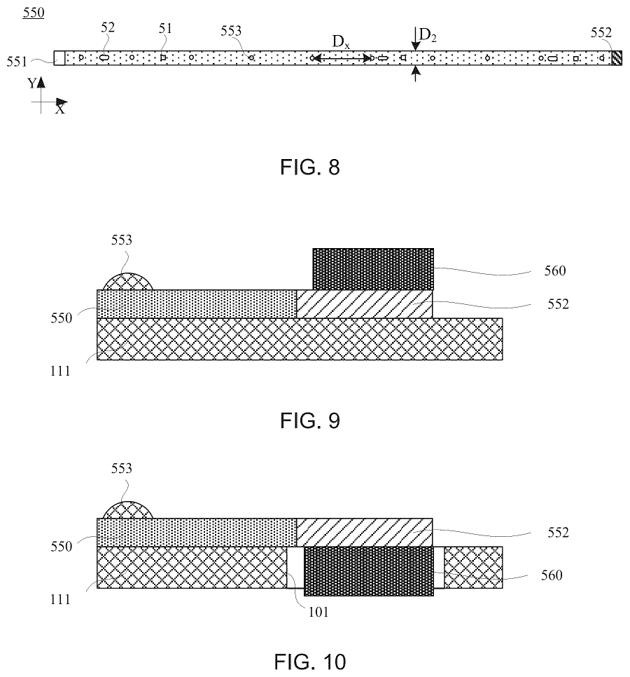

Referring to FIGS. 7 and 8, the two third structural members 550 are respectively located at both sides of the plurality of second structural members 530 in the second direction Y. The two third structural members 550 extend in the first direction X. An end of a third structural member 550 proximate to a first structural member 510 is provided with a second bonding portion 551 thereon, and an end of the third structural member 550 away from the first structural member 510 is provided with a third bonding portion 552 thereon. The second bonding portion 551 is connected to a second connector 540, and is connected to a first connector 520 connected to the plurality of first structural members 510 and located at the outermost side in the second direction Y through the second connector 540. The outlet connector 560 is connected to the third bonding portion 552. Based on this, the plurality of first structural members 510, the plurality of second structural members 530 and the two third structural members 550 may form a light-emitting substrate with a regular shape (e.g., a rectangle) together.

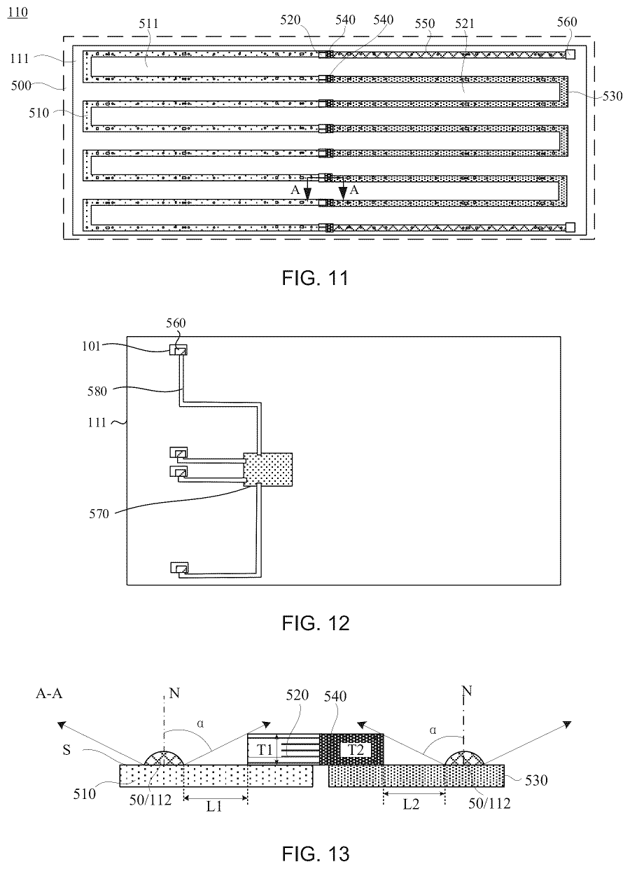

In some other embodiments, as shown in FIG. 11, the number of the second structural members 530 is one more than the number of the first structural members 510. The structural member group further includes two third structural members 550 and outlet connectors 560.

Referring to FIGS. 8 and 11, the two third structural members 550 are respectively located at both sides of the plurality of first structural members 510 in the second direction Y. The two third structural members 550 extend in the first direction X. An end of a third structural member 550 proximate to a second structural member 530 is provided with a second bonding portion 551 thereon, and an end of the third structural member 550 away from the second structural member 530 is provided with a third bonding portion 552 thereon. The second bonding portion 551 is connected to a first connector 520, and is connected to a second connector 540 connected to the plurality of second structural members 530 and located at the outermost side in the second direction Y through the first connector 520. The outlet connector 560 is connected to the third bonding portion 552. Based on this, the plurality of first structural members 510, the plurality of second structural members 530 and the two third structural members 550 may form a light-emitting substrate with a regular shape (e.g., a rectangle) together. It can be understood that the outlet connector may be a patch connector, and the patch connector is soldered to the third bonding portion 552.

In some embodiments, as shown in FIG. 8, the third structural member 550 includes a plurality of second electronic components 553 disposed at intervals in the first direction X, and an interval between two adjacent second electronic components 553 is equal to an interval between two adjacent first electronic components 50 in the first structural member 510 and an interval between two adjacent first electronic components 50 in the second structural member 530. That is, the distribution density of the second electronic components 553 is the same as the distribution density of the first electronic components 50, which is beneficial to ensuring the uniformity of light extraction of the light-emitting substrate when the third structural members 550 are combined with the first structural members 510 and the second structural members 530 to form the light-emitting substrate. The second electronic component 553 may be a light-emitting component. For example, the second electronic component 553 and the first electronic component 50 are light-emitting components of the same type.

For example, a dimension of the third structural member 550 in the second direction Y may be the same as a dimension of a main body portion of the structural member 3000 in the second direction Y, that is, the dimension of the third structural member 550 in the second direction Y is D₂. Of course, in some other embodiments, the dimension of the third structural member 550 in the second direction Y may be the same as or different from the dimension of the main body portion in the second direction Y. For example, the dimension of the third structural member 550 in the second direction Y is greater than the dimension of the main body portion in the second direction Y; alternatively, the dimension of the third structural member 550 in the second direction Y is less than the dimension of the main body portion in the second direction Y.

As shown in FIG. 8, similar to the first structural member 510 and the second structural member 530, the third structural member 550 may further include a plurality of driving elements 51 and fixing holes 52. The driving element 51 is used to drive at least one second electronic element 553 on the third structural member 550, and the fixing hole 52 is used to mount the third structural member 550 on the backplane.

In some embodiments, the third structural members 550 are aluminum-based structural members, which is beneficial to reduce the cost of the third structural member 550. The aluminum-based structural member includes a wiring layer. Based on this, referring to FIG. 9, the outlet connector 560 and the second electronic components 553 are disposed on a surface of the third structural member 550 away from the backplane 111.

In some other embodiments, the third structural members 550 are epoxy board (FR4) structural members. The epoxy board structural member may include double wiring layers which are located on opposite sides of a substrate layer, and the two wiring layers may be electrically connected through via holes. Referring to FIG. 10, the second electronic component 553 is disposed on a surface of the third structural member 550 away from the backplane 111, and the outlet connector 560 is disposed on a surface of the third structural member 550 proximate to the backplane 111. In this way, the outlet connector 560 may be disposed on a surface at a backlight side (a side away from the second electronic component 553) of the third structural member 550, so as to prevent the outlet connector 560 from blocking the light emitted by the second electronic component 553.

For example, in a case where the second electronic components 553 have a relatively small interval (e.g., the interval being in a range of 30 mm to 50 mm) therebetween, the third structural member 550 may adopt an epoxy board structural member, so that the outlet connector 560 may be prevented from blocking the light emitted by the second electronic component 553. In a case where the first electronic components 50 have a relatively large interval (e.g., the interval being greater than 50 mm) therebetween, the third structural member 550 may adopt an aluminum-based structural member. In this way, the manufacturing cost of the third structural member 550 may be reduced on a premise that the outlet connector 560 does not block the light emitted by the second electronic component 553.

In some embodiments, at least one of the first structural member 510 and the second structural member 530 is an aluminum-based structural member. For example, the first structural member 510 and the second structural member 530 are both aluminum-based structural members. Therefore, the first structural member 510 and the second structural member 530 being both aluminum-based structural members may reduce the manufacturing cost of the light-emitting substrate.

Referring to FIG. 12, the backplane 111 includes a plurality of avoidance holes 101, and each outlet connector 560 is provided in an avoidance hole 101. Thus, interference between the outlet connector 560 and the backplane 111 may be avoided, and the outlet connector 560 may be led to a side of the backplane away from the structural member group 500.

With reference to FIG. 12, the light-emitting substrate 110 further includes a driving circuit board 570 and a circuit board 580. The driving circuit board 570 is disposed on a surface of the backplane 111 away from the third structural member 550 (the structural member group 500). An end of the circuit board 580 is connected to the driving circuit board 570, and the other end of the circuit board 580 is connected to the outlet connector 560. For example, the driving circuit board 570 may be a flexible printed circuit (FPC) or a printed circuit board (PCB), and the circuit board 580 may be a flexible flat cable (FFC). The driving circuit board 570 transmits a control signal to the structural member group 500 through the circuit board 580 to control the structural member group 500 to emit light.

In some embodiments, the light-emitting substrate 110 includes a plurality of structural member groups 500 arranged in the second direction Y. FIG. 7 shows an example in which the light-emitting substrate 110 includes two structural member groups 500. It can be understood that the light-emitting substrate 110 may include one (as shown in FIG. 11), three, five or any other number of structural member groups 500, which are not listed one by one here. A plurality of third structural members 550 belonging to different structural member groups 500 are arranged at intervals in the second direction Y. In this way, the outlet connectors 560 connected to all structural member groups 500 being arranged in the second direction Y is conducive to reducing the difficulty of providing the circuit boards 580 and the outlet connectors 560.

In some embodiments, referring to FIG. 13, a first electronic component 50 on the first structural member 510, a first electronic component 50 the second structural member 530, and the second electronic component 553 are all light-emitting components 112. An included angle between a maximum light exit angle of a light-emitting component and a normal direction N of the light-emitting component is α. The luminous intensity corresponding to light, emitted along the normal direction N of the light exit surface S, in lights emitted by the light-emitting component 112 is defined as 1, and the luminous intensity of light emitted along the maximum light exit angle in this direction is half of the luminous intensity of the light emitted along the normal direction N.

A thickness of the first connector 520 is T1, a minimum distance between the first connector 520 and a light-emitting component 112 closest to the first connector 520 is L1, and the light-emitting component 112 closest to the first connector 520 is a light-emitting component 112 on the first structural member 510 closest to the first bonding portion 330. The minimum distance between the first connector 520 and the light-emitting component 112 refers to a minimum distance between contours of orthographic projections of the first connector 520 and the light-emitting component 112 on a surface of the first structural member 510 away from the backplane 111. T1≤L1×tan (90°−α). In this way, shielding of the light emitted by the light-emitting component 112 by the first connector 520 may be greatly reduced, and the risk of shadows on the light-emitting substrate may be reduced.

A thickness of the second connector 540 is T2, a minimum distance between the second connector 540 and a light-emitting component 112 closest to the second connector 540 is L2, and T2≤L2×tan (90°−α). In this way, shielding of the light emitted by the light-emitting component 112 by the second connector 540 may be greatly reduced, and the risk of shadows on the light-emitting substrate may be reduced.

Some embodiments of the present disclosure further provide a method for assembling a light-emitting substrate. The method for assembling the light-emitting substrate will be exemplarily described below by taking the light-emitting substrate shown in FIG. 7 as an example. First, first structural members and first connectors are connected to form first components, second structural members and second connectors are connected to form second components, and third structural members are each connected to both the second connector and the outlet connector to form third components. Then, the third components are mounted onto the backplane through fixing holes. A first connector of a first component is plugged into a second connector of a third structural member, and the first component is mounted and fixed on the backplane. Then, a second connector of a second component is plugged into another first connector of the first component, and the second component is mounted and fixed on the backplane, and so on. Finally, another third structural member is taken, a second connector of a third component is plugged into a first connector of the last first component, and the third component is mounted and fixed on the backplane, so as to complete assembly of a structural member group. For another structural member group, assembly is completed according to the above steps.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A structural member, comprising:
two main body portions, wherein the two main body portions extend in a first direction and have a first interval therebetween in a second direction, each main body portion includes a plurality of first electronic components disposed at intervals in the first direction; the first direction and the second direction intersect each other;
a connection portion extending in the second direction, wherein two ends of the connection portion are connected to ends of the two main body portions located on a same side; and
two first bonding portions connected to ends of the two main body portions away from the connection portion and configured to be connected to connectors.

2. The structural member according to claim 1, wherein an interval between two adjacent first electronic components in the second direction is D_{y}, a dimension of the main body portion in the second direction is D₂, and D_{y} and D₂ satisfy: D_{y}=3D₂+3M, where M is in a range of 0 mm to 2 mm, inclusive.

3. The structural member according to claim 1, wherein an interval between two adjacent first electronic components in the second direction is D_{y}, a dimension of the main body portion in the second direction is D₂, and D_{y} and D₂ satisfy: D_{y}=2D₂+2M, where M is in a range of 0 mm to 2 mm, inclusive.

4. The structural member according to claim 1, wherein the structural member is an aluminum-based structural member.

5. A light-emitting substrate, comprising a backplane and at least one structural member group disposed on the backplane, wherein the structural member group includes:
a plurality of first structural members, wherein each first structural member includes the structural member according to claim 1, the plurality of first structural members are disposed at intervals on the backplane in the second direction, and each first structural member has a first opening;
a plurality of first connectors, wherein each first bonding portion of the first structural member is connected to a first connector;
a plurality of second structural members, wherein each second structural member includes the structural member according to claim 1, the plurality of second structural members are disposed at intervals on the backplane in the second direction, each second structural member has a second opening, and an orientation of the first opening is opposite to an orientation of the second opening; and
a plurality of second connectors, wherein each first bonding portion of the second structural member is connected to a second connector; wherein
two first connectors connected to two adjacent first structural members and having a smallest distance in the second direction are respectively connected to two second connectors connected to a same second structural member; and two second connectors connected to two adjacent second structural members and having a smallest distance in the second direction are respectively connected to two first connectors connected to a same first structural member.

6. The light-emitting substrate according to claim 5, wherein a number of the first structural members is one more than a number of the second structural members; and the structural member group further includes:
two third structural members located at both sides of the plurality of second structural members in the second direction, wherein the two third structural members both extend in the first direction, an end of a third structural member proximate to a first structural member is provided with a second bonding portion thereon, and an end of the third structural member away from the first structural member is provided with a third bonding portion thereon; the second bonding portion is connected to a second connector, and is connected to a first connector connected to the plurality of first structural members and located at an outermost side in the second direction through the second connector; and
outlet connectors, an outlet connector being connected to the third bonding portion.

7. The light-emitting substrate according to claim 5, wherein a number of the second structural members is one more than a number of the first structural members; and the structural member group further includes:
two third structural members located at both sides of the plurality of first structural members in the second direction, wherein the two third structural members both extend in the first direction, an end of a third structural member proximate to a second structural member is provided with a second bonding portion thereon, and an end of the third structural member away from the second structural member is provided with a third bonding portion thereon; the second bonding portion is connected to a first connector, and is connected to a second connector connected to the plurality of second structural members and located at an outermost side in the second direction through the first connector; and
outlet connectors, an outlet connector being connected to the third bonding portion.

8. The light-emitting substrate according to claim 6, wherein the third structural member include a plurality of second electronic components disposed at intervals in the first direction, and an interval between two adjacent second electronic components is equal to an interval between two adjacent first electronic components in the first structural member and an interval between two adjacent first electronic components in the second structural member.

9. The light-emitting substrate according to claim 8, wherein the third structural members are aluminum-based structural members, and the outlet connector and the second electronic components are disposed on a surface of the third structural member away from the backplane.

10. The light-emitting substrate according to claim 8, wherein the third structural members are epoxy board structural members, the second electronic components are disposed on a surface of the third structural member away from the backplane, and the outlet connector is disposed on a surface of the third structural member proximate to the backplane; and
the backplane includes a plurality of avoidance holes, and each outlet connector is disposed in an avoidance hole.

11. The light-emitting substrate according to claim 10, further comprising:
a driving circuit board disposed on a surface of the backplane away from the third structural member; and
a circuit board, wherein an end of the circuit board is connected to the driving circuit board, and another end of the circuit board is connected to the outlet connectors.

12. The light-emitting substrate according to claim 6, wherein the light-emitting substrate comprises a plurality of structural member groups that are arranged in the second direction, and a plurality of third structural members belonging to different structural member groups are arranged at intervals in the second direction.

13. The light-emitting substrate according to claim 5, wherein first electronic components of the first structural member and first electronic components of the second structural member, and second electronic components of a third structural member included in the structural member group are all light-emitting components; an included angle between a maximum light exit angle of a light-emitting component and a normal direction of the light-emitting component is α;
a thickness of the first connector is T1, a distance between the first connector and a light-emitting component closest to the first connector in the first direction is L1, and T1≤L1×tan (90°−α); and
a thickness of the second connector is T2, a distance between the second connector and a light-emitting component closest to the second connector in the first direction is L2, and T2≤L2×tan (90°−α).

14. A backlight module, comprising:
the light-emitting substrate according to claim 5; wherein first electronic components of the first structural member and first electronic components of the second structural member, and second electronic components of a third structural member included in the structural member group all include light-emitting components.

15. A display device, comprising:
the backlight module according to claim 14; and
a display panel disposed on a light-exit side of the backlight module.

16. The light-emitting substrate according to claim 7, wherein the third structural members each include a plurality of second electronic components disposed at intervals in the first direction, and an interval between two adjacent second electronic components is equal to an interval between two adjacent first electronic components in the first structural member and an interval between two adjacent first electronic components in the second structural member.

17. The light-emitting substrate according to claim 16, wherein the third structural members are aluminum-based structural members, and the outlet connector and the second electronic components are disposed on a surface of the third structural member away from the backplane.

18. The light-emitting substrate according to claim 16, wherein the third structural members are epoxy board structural members, the second electronic components are disposed on a surface of the third structural member away from the backplane, and the outlet connector is disposed on a surface of the third structural member proximate to the backplane; and
the backplane includes a plurality of avoidance holes, and each outlet connector is disposed in an avoidance hole.

19. The light-emitting substrate according to claim 5, wherein a first connector and a second connector that are connected each other are board-to-board connectors.

20. The light-emitting substrate according to claim 11, wherein the driving circuit board is a flexible printed circuit or a printed circuit board, and the circuit board is a flexible flat cable.
